(19) United States
(12) Patent Application Publication
(10) Pub. No.: US 2020/0412084 A1
(43) Pub. Date: Dec. 31, 2020

(54) VERTICAL CAVITY SURFACE-EMITTING LASER, MANUFACTURING METHOD THEREOF, AND INSPECTION METHOD THEREOF

(71) Applicant: SUMITOMO ELECTRIC INDUSTRIES, LTD., Osaka (JP)

(72) Inventor: Yukihiro Tsuji, Osaka-shi (JP)

(73) Assignee: SUMITOMO ELECTRIC INDUSTRIES, LTD., Osaka (JP)

(21) Appl. No.: 16/888,919

(22) Filed: Jun. 1, 2020

(30) Foreign Application Priority Data
Jun. 28, 2019 (JP) 2019-121454

(51) Int. Cl. H01S 5/028; H01S 5/183; H01S 5/042; H01S 5/343

(52) U.S. Cl. CPC H01S 5/028; H01S 5/18347; H01S 5/18361; H01S 5/0422; H01S 2304/02; H01S 5/18311; H01S 5/04252; H01S 2304/04; H01S 5/34313

(57) ABSTRACT

A vertical cavity surface-emitting laser includes a first insulating film provided on a semiconductor layer, the first insulating film having a recess, an identification mark provided in the recess of the first insulating film, the identification mark being formed of a metal layer, and a second insulating film provided over the semiconductor layer and covering the first insulating film and the metal layer. The metal layer has an upper surface located at a height equal to or lower than an upper surface of the first insulating film.

### CROSS-REFERENCE TO RELATED APPLICATION

This application is based upon and claims the benefit of priority of the prior Japanese Patent Application No. 2019-121454, filed on Jun. 28, 2019, the entire contents of which are incorporated herein by reference.

### FIELD

The present invention relates to a vertical cavity surface-emitting laser, a method of manufacturing the same, and a method of inspecting the same.

### BACKGROUND

International Publication No. WO 2015/033649 (Patent Document 1) discloses a vertically cavity surface-emitting laser (VCSEL).

### SUMMARY

Appearance inspections of VCSELs are automated and performed using image-recognitions. In the appearance inspection, the image of the non-defective product serving as a standard is compared with the image of each chip to judge whether or not the chip is defective. However, since a different identification mark is printed on each chip of VCSEL, the identification mark may be detected as “defective”, even when the chip has no difference with the standard except for the identification mark. It is therefore an object of the present disclosure to provide a vertical cavity surface-emitting laser, a manufacturing method thereof, and an inspection method thereof, which can improve the accuracy of appearance inspection.

A vertical cavity surface-emitting laser according to the present disclosure includes a first insulating film provided on a semiconductor layer, the first insulating film having a recess, an identification mark provided in the recess of the first insulating film, the identification mark being formed of a metal layer, and a second insulating film provided over the semiconductor layer and covering the first insulating film and the metal layer. The metal layer has an upper surface located at a height equal to or lower than an upper surface of the first insulating film.

A method of manufacturing a vertical cavity surface-emitting laser according to the present disclosure includes steps of: providing a first insulating film on a semiconductor layer; providing a recess in the first insulating film; providing a metal layer in the recess; and providing a second insulating film over the semiconductor layer, the second insulating film covering the first insulating film and the metal layer. The metal layer forms an identification mark over the semiconductor layer, and the metal layer has an upper surface whose height is lower than or equal to an upper surface of the first insulating film.

An inspection method of the vertical cavity surface-emitting laser according to the present disclosure includes steps of: irradiating light to a vertical cavity surface-emitting laser from a direction inclined from a line along which the vertical cavity surface-emitting laser and a camera are aligned, obtaining an image of the vertical cavity surface-emitting laser by the camera, and judging whether or not the vertical cavity surface-emitting laser is good by collating the image with a standard image.

### BRIEF DESCRIPTION OF THE DRAWINGS

FIG. 1A is a plan view illustrating a vertical cavity surface-emitting laser according to a first embodiment,

FIG. 1B is a cross-sectional view illustrating the vertical cavity surface-emitting laser.

FIG. 2 is an enlarged cross-sectional view of a vicinity of an identification mark.

FIG. 3A and FIG. 3B are plan views illustrating methods of manufacturing a vertical cavity surface-emitting laser.

FIG. 4A and FIG. 4B are plan views illustrating methods of manufacturing the vertical cavity surface-emitting laser.

FIG. 5A and FIG. 5B are plan views illustrating methods of manufacturing the vertical cavity surface-emitting laser.

FIG. 6A and FIG. 6B are plan views illustrating methods of manufacturing the vertical cavity surface-emitting laser.

FIG. 7A and FIG. 7B are plan views illustrating methods of manufacturing the vertical cavity surface-emitting laser.

FIG. 8A and FIG. 8B are cross-sectional views showing a forming of an identification mark.

FIG. 9A and FIG. 9B are cross-sectional views showing the forming of an identification mark.

FIG. 10A is a schematic diagram illustrating an appearance inspection apparatus.

FIG. 10B is a flowchart illustrating an appearance inspection.

FIG. 11A and FIG. 11B are cross-sectional views illustrating a vicinity of an identification mark.

FIG. 12A and FIG. 12B are diagrams illustrating images.

FIG. 13 is a cross-sectional view illustrating a vertical cavity surface-emitting laser according to a comparative example.

### DESCRIPTION OF EMBODIMENTS

First, the contents of the embodiment of the present disclosure will be described.

An embodiment of the present disclosure is (1) a vertical cavity surface-emitting laser including a first insulating film provided on a semiconductor layer, the first insulating film having a recess, an identification mark provided in the recess of the first insulating film, the identification mark being formed of a metal layer, and a second insulating film provided over the semiconductor layer and covering the first insulating film and the metal layer. The metal layer has an upper surface located at a height equal to or lower than an upper surface of the first insulating film. Since the upper surface of the identification mark is depressed compared to a surface of the second insulating film covering the first insulating film, an image of the identification mark is hardly recognized in an appearance inspection. Thus the accuracy of the appearance inspection is improved.

(2) The semiconductor layer may be exposed at a bottom of the recess, the metal layer may be provided directly on the semiconductor layer, and the metal layer may have a thickness less than or equal to a thickness of the first insulating film. Since the metal layer does not protrude from the first insulating film. This makes the identification mark to be hardly recognized in the appearance inspection, thereby improving the accuracy of the appearance inspection.

(3) The thickness of the metal layer may be 200 nm or less, and the thickness of the second insulating film may be 200 nm or more. Since the metal layer does not protrude above the first insulating film, the surface of the second insulating film is nearly flat, and any steps are hardly formed in the surface. This makes it difficult to recognize the identification mark in the appearance inspection, thereby improving the accuracy of the appearance inspection.

(4) The recess may have an inner side wall apart from the metal layer by 1 μm or more and 10 μm or less. The second insulating film can have the surface being formed nearly flat, and the surface has no shadow originated from the identification mark. This makes it difficult to recognize the identification mark in the appearance inspection, thereby improving the accuracy of the appearance inspection.

(5) The second insulating film may include a silicon nitride film. Since the second insulating film has a high refractive index, light is reflected by the second insulating film and hardly reaches the metal layer. This makes it difficult to recognize the identification mark in the appearance inspection, thereby improving the accuracy of the appearance inspection.

(6) A method of manufacturing a vertical cavity surface-emitting laser includes steps of: providing a first insulating film on a semiconductor layer; providing a recess in the first insulating film; providing a metal layer in the recess; and providing a second insulating film over the semiconductor layer, the second insulating film covering the first insulating film and the metal layer. The metal layer forms an identification mark over the semiconductor layer, and the metal layer has an upper surface whose height is lower than or equal to an upper surface of the first insulating film. Since the identification mark is hardly recognized in the appearance inspection, the accuracy of the appearance inspection is improved.

(7) An inspection method for a vertical cavity surface-emitting laser includes steps of: irradiating light to a vertical cavity surface-emitting laser from a direction inclined from a line along which the vertical cavity surface-emitting laser and a camera are aligned, obtaining an image of the vertical cavity surface-emitting laser by the camera, and judging whether or not the vertical cavity surface-emitting laser is good by collating the image with a standard image. The light is reflected on the surface of the second insulating layer and difficult to reach the metal layer, since the metal layer is covered with the second insulating layer. In addition, the metal layer hardly affect a flatness of the surface of the second insulating layer, since the metal layer is formed inside the recess of the first insulating film. Thus the identification mark formed of the metal layer is hardly recognized in the appearance inspection. The accuracy of the appearance inspection is improved.

Specific examples of a vertical cavity surface-emitting laser, a manufacturing method thereof, and an inspection method thereof according to an embodiment of the present disclosure will be described below with reference to the drawings. It should be noted that the present disclosure is not limited to these examples, but is indicated by the claims, and it is intended to include all modifications within the meaning and range equivalent to the claims.

### First Embodiment

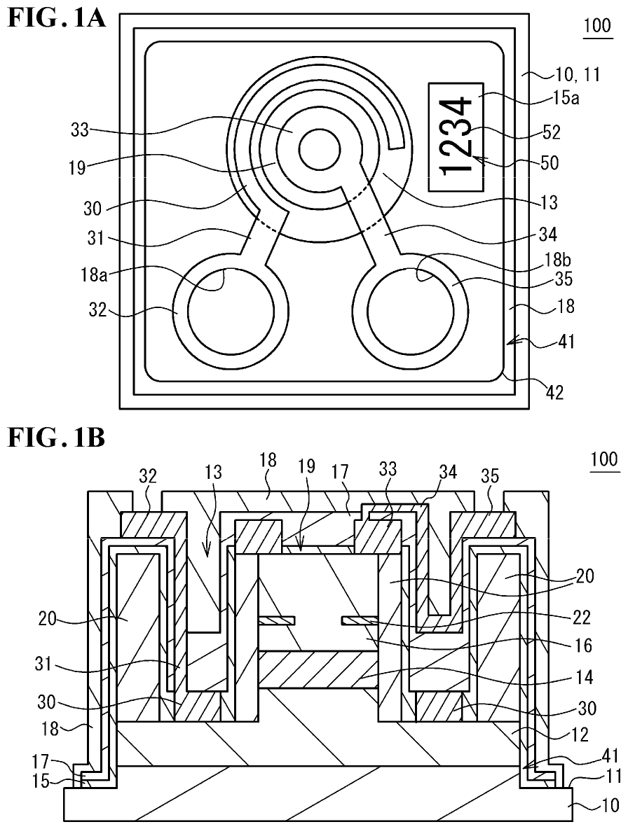

(Surface-Emitting Laser) FIG. 1A is a plan view illustrating a surface-emitting laser (vertical cavity surface-emitting laser) 100 according to the first embodiment, and FIG. 1B is a cross-sectional view illustrating the surface emitting laser 100. In FIG. 1A, an insulating film 18 and the like are seen through.

As illustrated in FIG. 1A, the surface-emitting laser 100 has a rectangular shape with a side of 200 μm to 300 μm, for example. A trench 11 for element isolation is provided in an outer peripheral portion of the surface-emitting laser 100, and a substrate 10 is exposed in the trench 11. Semiconductor layers, such as a lower reflector layer 12, an active layer 14, and an upper reflector layer 16, which will be described later, are located on the substrate 10 to form a mesa 41. The mesa 41 is surrounded by the trench 11, is rectangular, and has a chamfer 42 at each apex. A mesa 19, a pad 32, and a pad 35 are located inside the mesa 41 and are surrounded by the trench 11. A groove 13 is provided around the mesa 19. An electrode 33 is provided on the mesa 19, and the electrode 33 is electrically connected to the pad 35 by a wiring 34. An electrode 30 is provided in the groove 13, and the electrode 30 is electrically connected to the pad 32 by a wiring 31.

As illustrated in FIG. 1B, the surface-emitting laser 100 includes the substrate 10, the lower reflector layer 12, the active layer 14, and the upper reflector layer 16. The lower and upper reflector layers 12, 16 are DBRs (Distributed Bragg Reflectors).

The substrate 10 is, for example, a semi-insulating gallium arsenide (GaAs) semiconductor substrate. The lower reflector layer 12, the active layer 14, and the upper reflector layer 16 are sequentially stacked on the substrate 10, and these semiconductor layers form the mesa 19.

The lower reflector layer 12 is, for example, a semiconductor-multilayered film in which n-type aluminum gallium arsenide (AlₓGa₁₋ₓAs, 0≤x≤0.3 and Al_{y}Ga_{1-y}As, 0.7≤y≤1) having different compositions are alternately laminated with an optical film thickness λ/4.λis a wavelength of light emitted from the active layer 14. The lower reflector layer 12 is doped with, for example, silicon (Si). The lower reflector layer 12 includes a conductive contact layer in contact with the electrodes 30, and the contact layer is formed of, for example, AlGaAs.

The active layer 14 is formed of, for example, GaAs and indium gallium arsenide (InGaAs), and has a multiple quantum well (MQW) structure in which quantum well layers and barrier layers are alternately stacked. The active layer 14 has an optical gain. A cladding layer (not illustrated) may be interposed between the active layer 14 and the lower reflector layer 12, and between the active layer 14 and the upper reflector layer 16.

The upper reflector layer 16 is, for example, a semiconductor-multilayered film in which p-type AlₓGa₁₋ₓAs (0≤x≤0.3) and Al_{y}Ga_{1-y}As (0.7≤y≤1) are alternately laminated with an optical film thickness λ/4. The upper reflector layer 16 is doped with carbon (C), for example. The upper reflector layer 16 includes a conductive contact layer in contact with the electrodes 33, and the contact layer is formed of, for example, AlGaAs or GaAs.

The substrate 10, the lower reflector layer 12, the active layer 14, and the upper reflector layer 16 may be formed of other compound semiconductors. For example, the substrates 10 in addition to GaAs, may be such as AlₓGa₁₋ₓAs (0≤x≤0.2), which includes Ga and As.

A current confinement layer 22 is formed by selectively oxidizing a part of the upper reflector layer 16. The current confinement layer 22 is formed by oxidizing the periphery of the upper reflector layer 16, and the center of the upper reflector layer 16 is not oxidized. The current confinement layer 22 includes, for example, aluminum oxide (Al₂O₃) which is insulating in the periphery. Less current flows in the oxidized portion than in the portion that is not oxidized. Therefore, an unoxidized portion on the center of the upper reflector layer 16 becomes a current path, and efficient current injection to the active layer 14 becomes possible.

A high-resistance region 20 is formed on the outer side of the current confinement layer 22 and on the periphery portion of the mesa 19. The high-resistance region 20 is formed by implanting ions such as protons, for example. The groove 13 extends through the high-resistance region 20 in the thickness direction, reaches the lower reflector layer 12, and surrounds the mesa 19. The trench 11 is located outside the groove 13 and the high-resistance region 20, surrounds them, and reaches the substrate 10 in the thickness direction. A stack of the semiconductor layers forms the mesa 41 inside the trench 11.

An insulating film 15 (first insulating film) is formed of, for example, silicon oxynitride (SiON) or silicon oxide (SiO₂) having a thickness of 400 nm, and covers a surface of the high-resistance regions 20 and a surface of the mesas 19. An insulating film 17 (second insulating film) is formed of an insulator such as silicon nitride (SiN) having a thickness of 100 nm and a refractive index of 2.0, for example, and covers the insulating film 15. In order to reduce a parasitic capacitance, the dielectric constants of the insulating films 15 and 17 are preferably low. The insulating films 15 and 17 function as a part of reflective films for reflecting light emitted from the active layer 14, and the thicknesses and refractive indices are determined so as to increase the reflectance. The insulating film 18 (second insulating film) is formed of, for example, SiN having a thickness of 100 nm and a refractive index of 2.0, and covers the insulating film 17. The insulating film 18 has an opening 18a through which the pad 32 is exposed and an opening 18b through which the pad 35 is exposed.

The electrode 30 is for an negative-side electrode having a laminated structure of gold (Au), germanium (Ge), and nickel (Ni), and is provided inside the groove 13 and on the contact layer in the lower reflector layer 12. The electrode 33 is for a positive-side electrode having a stacked structure of titanium (Ti), platinum (Pt), and Au, and is provided on the mesa 19 and on the surface of the contact layer in the upper reflector layer 16. The electrodes 30 and 33 are ohmic electrodes. The pads 32 and 35 are located outside the mesa 19 and above the high resistance region 20. The wiring 31 and the pad 32 are electrically connected to the electrode 30, and the electrode 30 is electrically connected to the lower reflector layer 12 through an opening of the insulating film 17. The wiring 34 and the pad 35 are electrically connected to the electrode 33, and the electrode 33 is electrically connected to the upper reflector layer 16. The wirings 31, 34 and the pads 32, 35 are made of Au.

As illustrated in FIG. 1A, the surface-emitting laser 100 is provided with an identification mark 50 for traceability, and the identification mark 50 is illustrated in perspective view of the insulating films 17 and 18. The insulating film 15 has a recess 15a with, for example, a rectangular shape. A metal layer 52 is provided on a bottom of the recess 15a. A length of a short side of the recess 15a is, for example, 25 μm to 30 μm, and a length of a long side is, for example, 100 μm to 120 μm.

The identification mark 50 is made of the metal layer 52. Each of the identification marks 50 is respectively given to each of the surface-emitting lasers 100. The identification mark 50 in FIG. 1A is “1234”. Each identification mark 50 has, for example, four characters. One character of the identification mark 50 falls within an area of a rectangle having a side of 25 μm to 30 μm, for example. As will be described later, the identification mark 50 is not recognized in the appearance inspection, but the identification mark 50 can be recognized when the surface-emitting laser 100 is viewed from a normal direction and with an appropriate illumination. The identification mark 50 may be less than four or more than four numerals, or may be a character such as an alphabet, a symbol such as “+”, or a combination thereof in addition to the numerals.

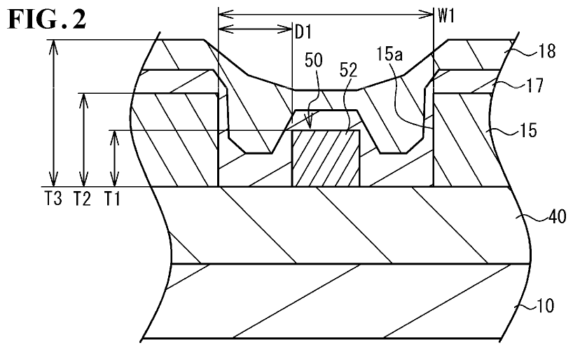

FIG. 2 is an enlarged cross-sectional view of a vicinity of the identification mark 50. A semiconductor layer 40 illustrated in FIG. 2 includes the lower reflector layer 12, the active layer 14, the upper reflector layer 16, and the high-resistance region 20. As illustrated in FIG. 2, the recess 15a is provided in the insulating film 15, and a surface of the semiconductor layer 40 is exposed at a bottom of the recess 15a. The metal layer 52 is provided inside the recess 15a on the surface of the semiconductor layer 40. Specifically, the metal layer 52 is disposed on a surface of the high resistance region 20. The metal layer 52 forms the identification mark 50 as illustrated in FIG. 1A. The metal layer 52 is formed by, for example, the same stacked structure of Ti/Pt/Au as the electrode 33. The metal layer 52 is separated from the electrodes 30, 33 and is not electrically connected thereto. The insulating film 17 covers the insulating film 15 and the metal layer 52, and the insulating film 18 covers the insulating film 17. The insulating film 17 has concavities and convexities corresponding to the recess 15a and the metal layer 52. The insulating film 18 is slightly recessed above the recess 15a, but is flatter than the insulating film 17. The insulating film 18 has a smoother surface than the insulating film 17.

A thickness T1 of the metal layer 52 is equal to or less than the thickness T2 of the insulating film 15, and an upper surface of the metal layer 52 is located at a height equal to or less than an upper surface of the insulating film 15. That is, the metal layer 52 does not protrude above the insulating film 15. The thickness T1 of the metal layer 52 is, for example, 200 nm or less, and the thickness T2 of the insulating film 15 is, for example, 400 nm. The thickness of each of the insulating films 17 and 18 is 100 nm, and the thickness T3 of the three insulating films with respect to the upper surface of the semiconductor layer 40 is 600 nm. A width W1 of the recess 15a is, for example, 30 μm, and a distance D1 from an inner side wall of the recess 15a to an end of the metal layer 52 is, for example, 1 μm or more and 10 82 m or less.

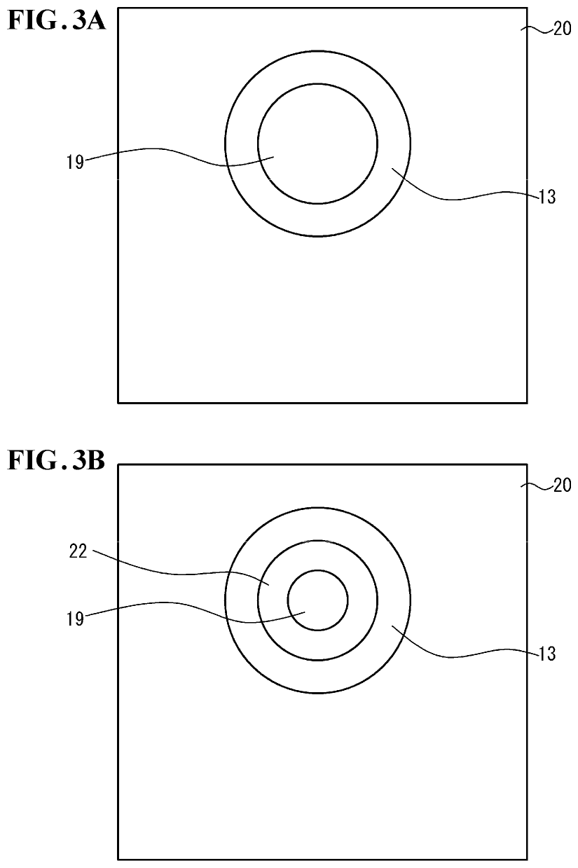

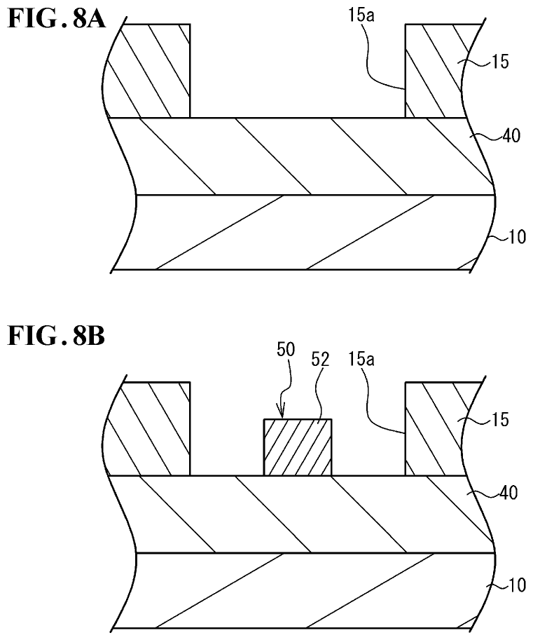

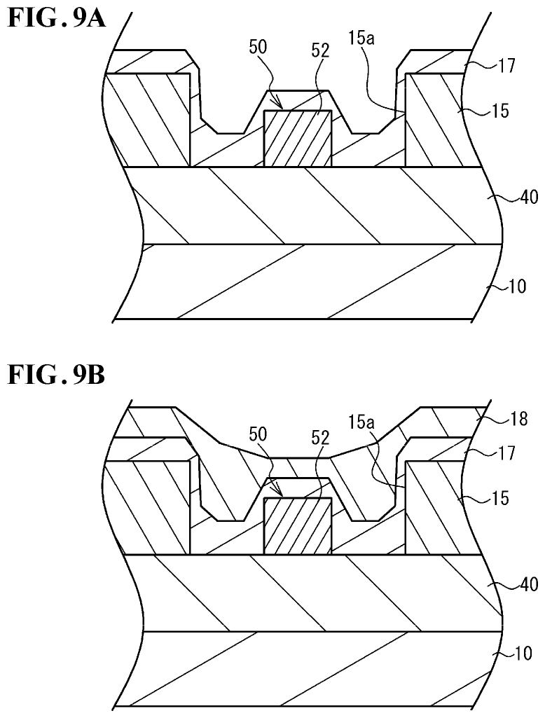

(Manufacturing Method) Next, a method of manufacturing the surface-emitting laser 100 will be described. FIG. 3A to FIG. 7B are plan views illustrating manufacturing methods of the surface-emitting lasers 100. FIG. 8A to FIG. 9B are cross-sectional views illustrating the forming of the identification mark 50.

First, the lower reflector layer 12, the active layer 14, and the upper reflector layer 16 are epitaxially grown in this order on the substrate 10 by, for example, a metal-organic vapor phase epitaxy (MOCVD) method or a molecular beam epitaxy (MBE) method. The upper reflector layer 16 includes a AlₓGa₁₋ₓAs layer (0.9≤x≤1.0) for forming the current confinement layer 22.

As illustrated in FIG. 3A, the high-resistance region 20 is formed by ion implantation. Specifically, for example, a photoresist having a thickness of 10 μm or more and 15 μm or less is spin-coated on the semiconductor. A resist mask is formed from the photoresist using a photolithography using ultraviolet (UV) light and an alkaline solution. For example, ions such as proton (H⁺) are implanted to form the high-resistance region 20. The proton is not implanted into a portion of the semiconductor layer masked with the photoresist, and the proton is implanted into a portion exposed from the photoresist. The implantation depth is, for example, 5 μm from a surface of the semiconductor layer. After the ion implantation, the resist mask is removed by an organic solvent and an ashing with an oxygen plasma.

As illustrated in FIG. 3A, the mesa 19 is formed by dry etching of the high-resistance region 20 by using, for example, inductively coupled plasma reactive ion etching (ICP-RIE). At this time, the groove 13 reaching the lower reflector layer 12 is formed in the high resistance region 20, and a portion which is not etched is protected by a photoresist (not illustrated). As an etching gas, for example, a BCl₃ gas or a mixed gas of BCl₃ and Cl₂ is used. Examples of etching conditions are shown below.
BCl₃/Ar=30 sccm/70 sccm
(or BCl₃/Cl₂/Ar=20 sccm/10 sccm/70 sccm)
ICP power: 50 W to 1000 W
Bias power: 50 W to 500 W
Substrate temperature: 25° C. or less

As illustrated in FIG. 3B, a portion of the upper reflector layer 16 of the mesa 19 is oxidized from the end portion of the mesa 19 by heating the upper reflector layer 16 to about 400° C. in a steam atmosphere, for example, to form the current confinement layer 22. The heating time is determined so that the current confinement layer 22 reaches a predetermined width and an unoxidized portion having a predetermined width remains inside the current confinement layer 22.

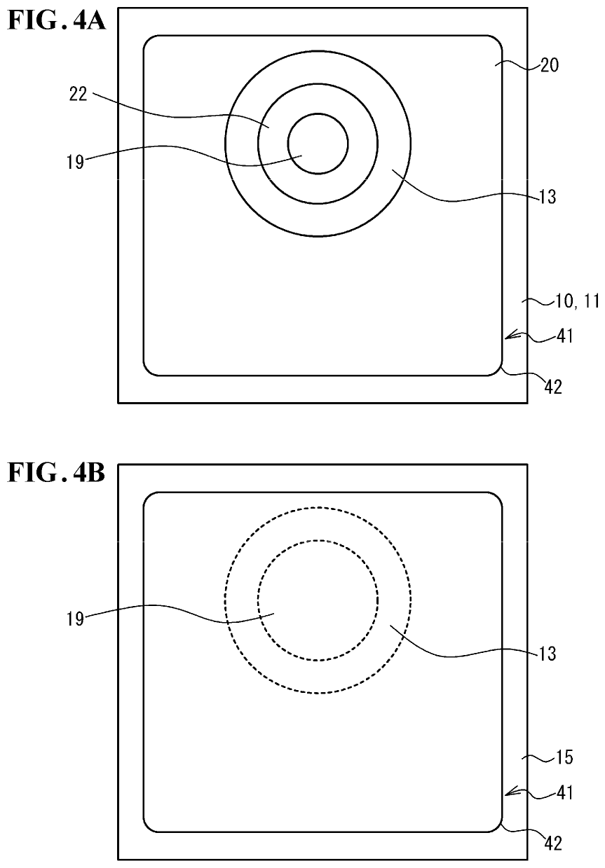

As illustrated in FIG. 4A, the trenches 11 are formed by dry-etching of the high-resistance region 20, the lower reflector layer 12, and the substrate 10. At this time, portions not etched such as the mesa 19 and the groove 13 are covered with a photoresist (not illustrated). As an etching gas, for example, a BCl₃ gas or a mixed gas of BCl₃ and Cl₂ is used. Examples of the etching conditions are shown below.
BCl₃/Ar=30 sccm/70 sccm
(or BCl₃/Cl₂/Ar=20 sccm/10 sccm/70 sccm)
ICP power: 50 W to 1000 W
Bias power: 50 W to 500 W
Substrate temperature: 25° C. or less

A depth of the trench 11 is, for example, 7 μm, and the substrate 10 is exposed in the trench 11. The mesa 41 having the chamfer 42 is formed inside the trench 11. Since the lower reflector layer 12, the active layer 14, and the upper reflector layer 16 are separated between the plurality of surface-emitting lasers 100, the plurality of surface-emitting lasers 100 are electrically separated. The distance between adjacent surface-emitting lasers 100 is, for example, 30 μm to 60 μm.

As illustrated in FIG. 4B, the insulating film 15 covering the wafer is formed by, for example, plasma-enhanced chemical vapor deposition (PECVD). The insulating film 15 is, for example, a SiON film or a SiO₂ film.

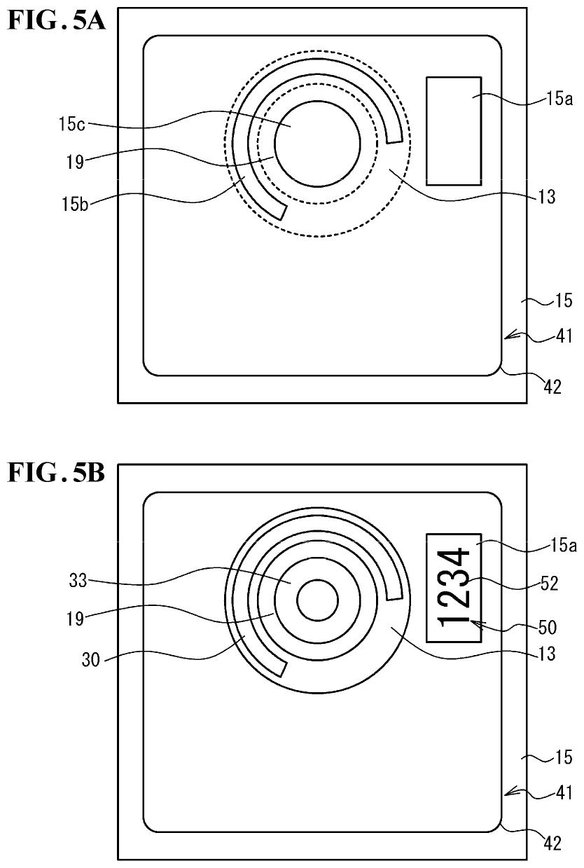

As illustrated in FIG. 5A, the recess 15a, an opening 15b, and an opening 15care formed in the insulating film 15 by forming resist patterns, etching, and the like. The opening 15b is located in the groove 13 and the opening 15c is located on the mesa 19. As illustrated in FIG. 8A, a surface of the semiconductor layer 40, i.e., a surface of the high-resistance region 20, is exposed in a bottom of the recess 15a.

As illustrated in FIG. 5B, the electrode 30 is formed on a surface of the lower reflector layer 12 in the opening 15b by resist-patterning and vacuum-evaporation. The electrode 33 is formed on a surface of the upper reflector layer 16 in the opening 15c, and the metal layer 52 is formed on the surface of the semiconductor layer 40 in the recess 15a as illustrated in FIG. 8B. After the electrodes 30 and 33 are formed, heat treatment is performed at a temperature of, e.g., about 400° C. for 1 minute, whereby ohmic contacts are made between the electrodes 30, 33 and the semiconductor layers. The electrode 30 is electrically connected to the lower reflector layer 12, and the electrode 33 is electrically connected to the upper reflector layer 16. The metal layer 52 forms the identification mark 50.

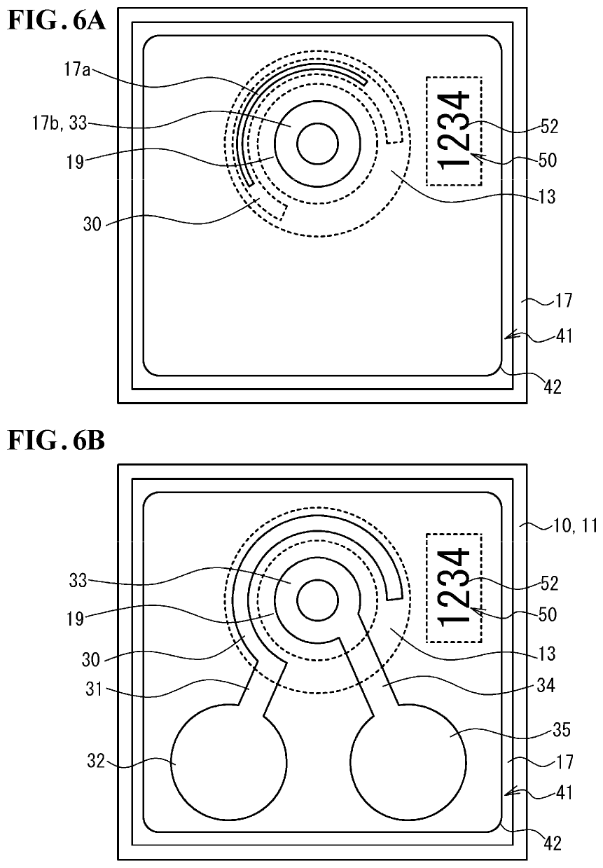

As illustrated in FIG. 6A, the insulating film 17 is formed on the insulating film 15, the electrodes 30 and 33, and the identification mark 50 by, for example, PECVD. The insulating film 17 is formed of an insulator such as SiN. By etching the insulating film 17 by using a resist-pattern, the opening 17a through which the electrode 30 is exposed and the opening 17b through which the electrode 33 is exposed are formed in the insulating film 17.

As illustrated in FIG. 6B, the wiring 31 and the pad 32 which are connected to the electrode 30 are formed by a plating process or the like, and the wiring 34 and the pad 35 which are connected to the electrode 33 are formed by the plating process or the like. Portions of the insulating films 15 and 17 in the trench 11 are etched to expose the substrate 10 in the trench 11. As illustrated in FIG. 9A, the metal layer 52 is covered with the insulating film 17, and the metal layer 52 is not exposed from the insulating film 17. Further, any plating layer is not provided on the metal layer 52.

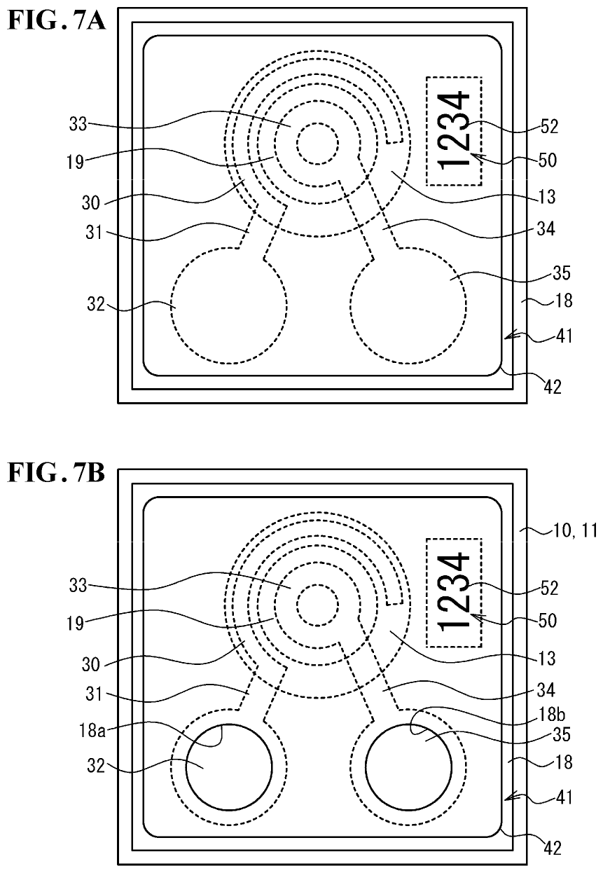

As illustrated in FIG. 7A, the insulating film 18 is formed by, e.g., PECVD. The insulating film 18 is a passivation film formed of an insulator such as SiN, and covers the insulating film 17, the wirings 31 and 34, the identification mark 50, and the pads 32 and 35.

As illustrated in FIG. 7B, a part of the insulating film 18 is etched to form the opening 18a through which the pad 32 is exposed and the opening 18b through which the pad 35 is exposed. A portion of the insulating film 18 in the trench 11 is also etched to expose the substrate 10 in the trench 11. As illustrated in FIG. 9B, the metal layer 52 is covered with the insulating film 18 from above the insulating film 17, and the metal layer 52 is not exposed. A back surface of the substrate 10 is polished by using a back grinder or a lapping apparatus to obtain a thickness of about 100 μtm to 200 μm. By using a blade or the like, the substrate 10 is cut in the trench 11 to form a plurality of the surface-emitting lasers 100 from the substrate 10.

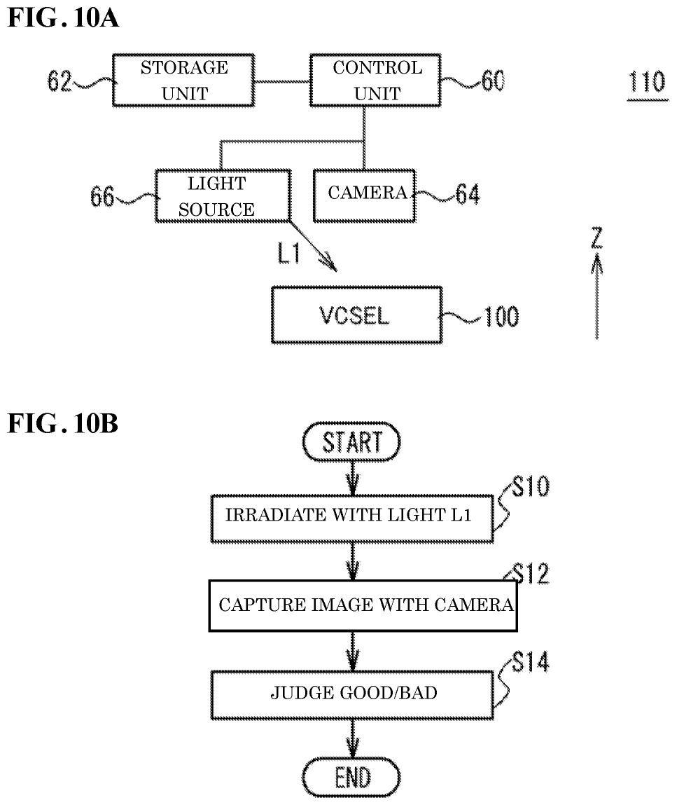

(Appearance inspection) An appearance inspection of the surface-emitting laser 100 will be described. FIG. 10A is a schematic diagram illustrating the appearance inspection apparatus 110. As illustrated in FIG. 10A, the appearance inspection apparatus 110 includes a control unit 60, a storage unit 62, a camera 64, and a light source 66. The control unit 60 includes, for example, a central processing unit (CPU) or the like. The storage unit 62 is, for example, a hard disk drive (HDD) or a solid state drive (SSD), and stores a non-defective image (registered image) serving as a standard for appearance inspection. The camera 64 includes, for example, a microscope and a camera. The surface-emitting laser 100 is disposed directly below the camera 64. A direction of a line along which the camera 64 and the surface-emitting laser 100 are aligned is defined as a Z-axis direction. The light source 66 is, for example, a ring-shaped fluorescent lamp or a light-emitting diode surrounding the camera 64, and emits a light L1 which is white light.

FIG. 10B is a flowchart illustrating the appearance inspection. As illustrated in FIG. 10B, the light source 66 irradiates the surface-emitting laser 100 with the light L1 in step S10. In step S12, the camera 64 captures an image of the surface-emitting laser 100. In step S14, the control unit 60 compares the captured image with the registered image stored in the storage unit 62, and judges whether the surface-emitting laser 100 is a non-defective product or a defective product. Thus, the appearance inspection is completed.

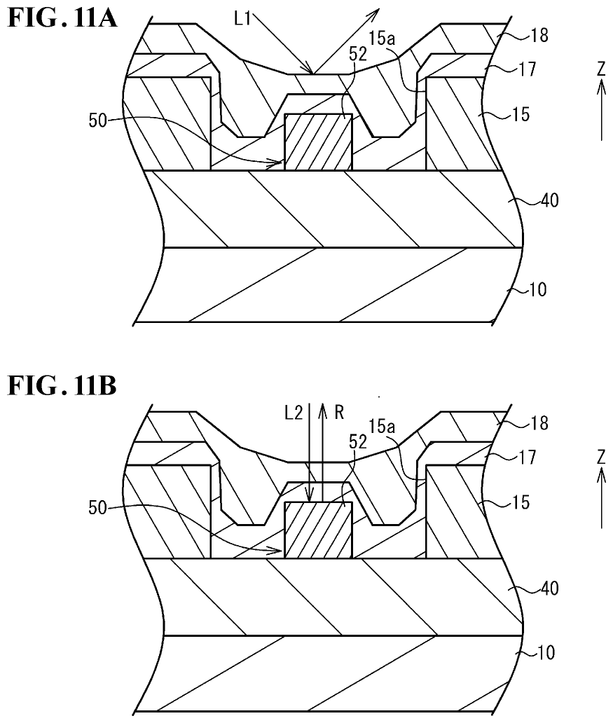

FIG. 11A and FIG. 11B are cross-sectional views illustrating a vicinity of the identification mark 50. FIG. 11A illustrates the appearance inspection. As illustrated in FIG. 11A, the light source 66 irradiates the light L1 from a direction inclined with respect to the Z-axis direction. Since the light L1 is reflected by the surface of the insulating film 18, the light L1 does not easily enter an inside of the insulating film 18. In addition, the metal layer 52 does not protrude above the insulating film 15, and no clear step corresponding to the identification mark 50 is formed on the surface of the insulating film 18. The second insulating film can have the surface being formed nearly flat, and the surface has no shadow originated from the identification mark. Therefore, the identification mark 50 does not easily appear on the image captured by the camera 64.

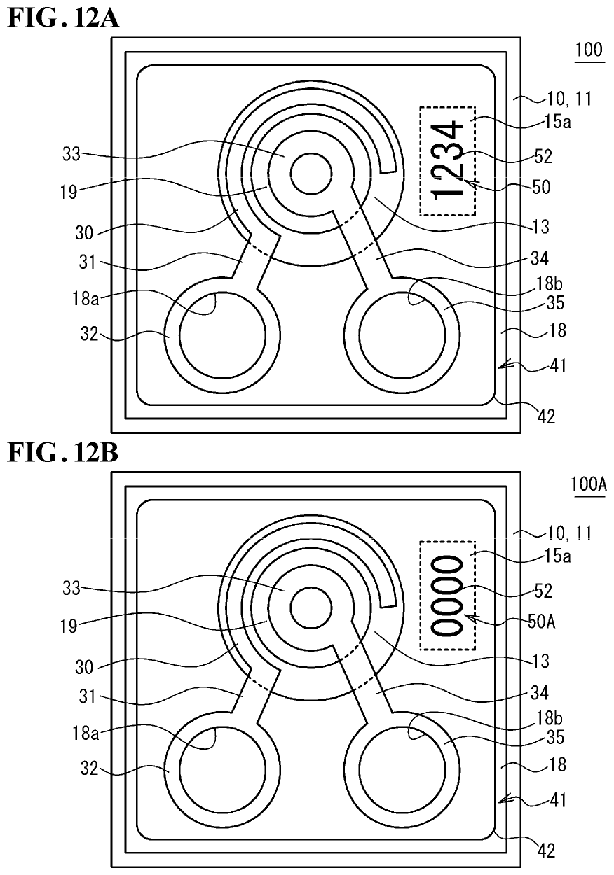

FIG. 12A and FIG. 12B are diagrams illustrating images. FIG. 12A is an image of the surface-emitting laser 100 imaged in the appearance inspection. FIG. 12B is an image of the surface-emitting laser 100A which is a non-defective product, and is the registered image stored in the storage unit 62. The identification mark 50 illustrated in FIG. 12A is “1234”. On the other hand, the identification mark 50A of the registered image illustrated in FIG. 12B is “0000”. Although the identification mark 50 is different from the identification mark 50A, the control unit 60 does not recognize the identification marks 50 and 50A because the light L1 is reflected by the insulating film 18 as illustrated in FIG. 11A. Therefore, it is possible to perform high-precision quality determination regardless of the difference in the identification marks.

FIG. 11B illustrates how to recognize the identification mark 50. As illustrated in FIG. 11B, the surface-emitting laser 100 is irradiated with another light L2 including green light having a narrow spectrum of wavelength range from 495 nm to 570 nm. The light L2 is irradiated from the Z-axis direction. Green light having a wavelength of 495 nm to 570 nm in the light L2 passes through the insulating films 18 and 17. When the camera 64 captures an image of the surface-emitting laser 100 under this irradiation, the identification mark 50 can be recognized from the image. This makes it possible to secure traceability.

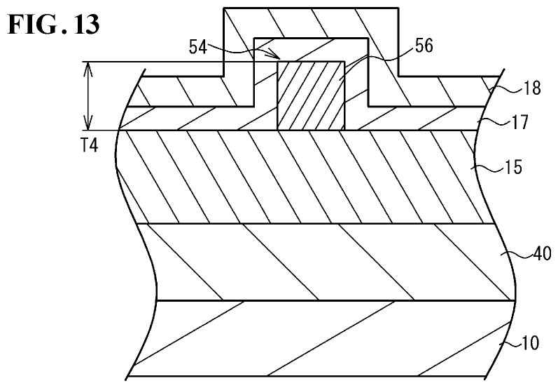

(Comparative Example) FIG. 13 is a cross-sectional view illustrating a surface-emitting laser according to a comparative example, and a vicinity of an identification mark 54 is enlarged. A metal layer 56 is provided on an upper surface of the insulating film 15, protrudes from the upper surface of the insulating film 15, and forms the identification mark 54. The insulating films 17 and 18 cover the metal layer 56. The thickness T4 of the metal layer 56 is, for example, 1.5 μm.

In the comparative example, the identification mark 54 forms a step. For this reason, the identification mark 54 is recognized in the image in the appearance inspection. Since the identification mark 54 differs from the registered image, the control unit 60 may judge that the surface-emitting laser is a defective product. As a result, the accuracy of the inspection is lowered, and many surface-emitting lasers would erroneously be judged as defective in spite of being non-defective. An area including the identification mark 54 could be masked in the appearance inspection. In that case, differences in the identification marks would not affect the appearance inspection. However, an appearance abnormality in a vicinity of the identification mark 54 might be erroneously overlooked.

According to the first embodiment, the metal layer 52 forms the identification mark 50, the upper surface of the metal layer 52 is located at a height lower than the upper surface of the insulating film 15, and the insulating film 18 covers the metal layer 52. In the appearance inspection, the light L1 of the light source 66 is reflected by the insulating film 18, and the step corresponding to the metal layer 52 is not significant at the surface of the insulating film 18, so that the identification mark 50 is hardly recognized. Therefore, the difference in the identification marks between the registered image and the captured image does not affect the appearance inspection. Surface above the identification mark 50 can be inspected in the scope of appearance inspection. As a result, the accuracy of the appearance inspection is improved, and erroneous determination can be suppressed.

As illustrated in FIG. 2, the semiconductor layer 40 is exposed from the recess 15a of the insulating film 15, and the metal layer 52 is provided on the exposed semiconductor layer 40. Since the thickness T1 of the metal layer 52 is equal to or less than the thickness T2 of the insulating film 15, the metal layer 52 does not protrude above the insulating film 15. Therefore, the identification mark 50 is hardly recognized in the appearance inspection, and the accuracy of the appearance inspection is improved.

The thickness T1 of the metal layer 52 is, for example, 200 nm or less, and the thickness T2 of the insulating film 15 is 200 nm or more. The metal layer 52 does not protrude above the insulating film 15, and the metal layer 52 is buried in the recess 15a, so that a step is hardly formed. The identification mark 50 is hardly recognized in the appearance inspection, and the accuracy of the appearance inspection is improved.

If the distance D1 between the metal layer 52 and the inner side wall of the recess 15a is increased, the insulating film 18 may form a step along the recess 15a and the metal layer 52, and the identification mark 50 may be recognized in the appearance inspection. The distance D1 is preferably 1 μm or more and 10 μm or less, for example. Since the insulating film 18 is nearly flat above the metal layer 52, the identification mark 50 is hardly recognized in the appearance inspection.

The insulating film 18 is, for example, an SiN film, and has a refractive index of 2.0. The light L1 emitted from the light source 66 is reflected by the surface of the insulating film 18 due to its high refractive index. Therefore, the identification mark 50 is hardly recognized in the appearance inspection, and the accuracy of the appearance inspection is improved. It is preferable that the insulating film 18 has a refractive index and a thickness such that the insulating film 18 reflects the light L1 of the light source 66, and transmits green light having a wavelength of 495 nm to 570 nm included in the light L2.

Although the embodiments of the present disclosure have been described above in detail, the present disclosure is not limited to the specific embodiments, and various modifications and variations are possible within the scope of the gist of the present disclosure described in the claims.

What is claimed is:

1. A vertical cavity surface-emitting laser comprising:
a first insulating film provided on a semiconductor layer, the first insulating film having a recess;
an identification mark provided in the recess of the first insulating film, the identification mark being formed of a metal layer; and
a second insulating film provided over the semiconductor layer, the second insulating film covering the first insulating film and the metal layer,
wherein
the metal layer has an upper surface located at a height equal to or lower than an upper surface of the first insulating film.

2. The vertical cavity surface-emitting laser according to claim 1, wherein
the semiconductor layer is exposed at a bottom of the recess,
the metal layer is provided directly on the semiconductor layer, and
the metal layer has a thickness less than or equal to a thickness of the first insulating film.

3. The vertical cavity surface-emitting laser according to claim 1, wherein
the thickness of the metal layer is 200 nm or less, and
the second insulating film has a thickness of 200 nm or more.

4. The vertical cavity surface-emitting laser according to claim 1, wherein the recess has an inner side wall apart from the metal layer by 1 μm or more and 10 μm or less.

5. The vertical cavity surface-emitting laser according to claim 1, wherein the second insulating film includes a silicon nitride film.

6. A method of manufacturing a vertical cavity surface-emitting laser comprising steps of:
providing a first insulating film on a semiconductor layer;
forming a recess in the first insulating film;
providing a metal layer in the recess; and
providing the second insulating film covering the first insulating film and the metal layer,
wherein
the metal layer forms an identification mark over the semiconductor layer, and
the metal layer has an upper surface whose height is lower than or equal to an upper surface of the first insulating film.

7. A method of inspecting a vertical cavity surface-emitting laser comprising steps of:
irradiating light to a vertical cavity surface-emitting layer from a direction inclined from a line along which the vertical cavity surface-emitting laser and a camera are aligned;
obtaining an image of the vertical cavity surface-emitting laser by the camera; and
judging whether or not the vertical cavity surface-emitting laser is non-defective by collating the image with a standard image.
